(19) United States
(12) Patent Application Publication
(10) Pub. No.: US 2012/0104403 A1
(43) Pub. Date: May 3, 2012

(54) THIN FILM TRANSISTOR AND METHOD FOR PRODUCING THE SAME

(75) Inventors: Akihiko Kohno, Osaka (JP); Masao Moriguchi, Osaka (JP); Yuhichi Saitoh, Osaka (JP)

(73) Assignee: SHARP KABUSHIKI KAISHA, Osaka (JP)

(21) Appl. No.: 13/381,282

(22) PCT Filed: Feb. 22, 2010
(86) PCT No.: PCT/JP2010/052602

§ 371 Date: Jan. 10, 2012

(30) Foreign Application Priority Data
Jul. 3, 2009 (JP) 2009-159200

(51) Int. Cl. H01L 29/786; H01L 29/04; H01L 21/336

(52) U.S. Cl. 257/66; 438/158; 257/E29.294; 257/E21.414

(57) ABSTRACT

An object of the present invention is to provide a thin film transistor having a gate insulating film for suppressing a shift amount of a threshold voltage generated by use under a high temperature environment. In a thin film transistor having a channel layer made of microcrystalline silicon, a gate insulating film 140 is a film obtained by laminating a first silicon nitride film 141 having a nitrogen concentration of 6×10²¹ atoms/cc or less and a second silicon nitride film 142 having a nitrogen concentration higher than 6×10²¹ atoms/cc. Therefore, the second silicon nitride film 142 increases the blocking effect against mobile ions entering from a glass substrate 20 to make the mobile ions less likely to be stored in an interface with a channel layer 50. The first silicon nitride film 141 increases the dielectric breakdown voltage of the gate insulating film 140.

### TECHNICAL FIELD

The present invention relates to a thin film transistor and a manufacturing method thereof, and particularly, to a thin film transistor suited for a driver circuit of an active matrix type display device and a manufacturing method thereof.

### BACKGROUND ART

In recent years, a liquid crystal display device that is called a “monolithic driver type liquid crystal display device” in which driver circuits, such as a gate driver, a source driver, and the like, are integrally formed in a frame section of a liquid crystal panel has been manufactured.

When a driver circuit of such a liquid crystal display device is formed of thin film transistors (Thin Film Transistors, hereinafter referred to as “TFTs”) made of amorphous silicon, there is a problem that the operation speed of the driver circuit slows down because the mobility of the amorphous silicon is low. In addition, when a TFT having a channel layer that is made of amorphous silicon (hereinafter referred to as an “amorphous silicon TFT) undergoes a gate bias stress test in which a constant voltage is applied to its gate electrode for a long time, there is another problem that the threshold voltage shifts significantly, damaging the amorphous silicon TFT. Here, the gate bias stress test is an accelerated test that is performed in order to observe, in a short period of time, the changes in the threshold voltage of a TFT over a long period of time.

Thus, in order to increase the operation speed of a driver circuit and decrease the shift amount in the threshold voltage caused by the gate bias stress test, a driver circuit that is constituted of a silicon nitride (SiNx) film, which has a high blocking effect against mobile ions that cause shifts in the threshold voltage, such as sodium ions (Na⁺) and the like, as a gate insulating film and a TFT made of microcrystalline silicon (hereinafter referred to as a “microcrystalline silicon TFT”), which has a higher crystallinity than amorphous silicon, as a channel layer is beginning to be used.

With respect to this, Japanese Patent Gazette No. 3072000 and Japanese Patent Application Laid-Open Publication No. 2000-340799 indicate that using a silicon oxynitride film or a silicon nitride film in which the nitrogen concentration is controlled to improve the blocking effect against mobile ions as a gate insulating film makes the mobile ions less likely to enter the gate insulating film.

### RELATED ART DOCUMENTS

### Patent Documents

Patent Document 1: Japanese Patent Gazette No. 3072000
Patent Document 2: Japanese Patent Application Laid-Open Publication No. 2000-340799

### SUMMARY OF THE INVENTION

### Problems to be Solved by the Invention

A liquid crystal display device that is installed in an environment where the temperature can become high, such as a liquid crystal display device equipped in a car or the like, is required to operate normally even under a high temperature environment. However, when a microcrystalline silicon TFT undergoes a gate bias stress test, there is a problem that the shift amount of the threshold voltage under a high temperature environment is larger than the shift amount of the threshold voltage under an environment at room temperature. It can be considered that the shift amount of the threshold voltage increases under a high temperature environment as described above due to the synergistic effect of increased dangling bonds caused by hydrogen leaving the microcrystalline silicon film and mobile ions, which are likely to enter the gate insulating film.

Here, it can be considered that the mobile ions are likely to enter the gate insulating film because the nitrogen concentration inside the silicon nitride film, which functions as the gate insulating film, is not optimized, thereby making the blocking effect against the mobile ions insufficient. Thus, the gate insulating film of the microcrystalline silicon TFT needs to be optimized in order to prevent such problems from occurring during a gate bias stress test under a high temperature environment. Japanese Patent Gazette No. 3072000 and Japanese Patent Application Laid-Open Publication No. 2000-340799 do not discuss an optimization of the gate insulating film in order to prevent problems from occurring under a high temperature environment.

Thus, the object of the present invention is to provide a thin film transistor having a gate insulating film that reduces the shift amount of the threshold voltage generated by use under a high temperature environment.

### Means for Solving the Problems

A first aspect of the present invention is a thin film transistor formed on an insulating substrate that includes a gate electrode, a gate insulating film, and a channel layer made of microcrystalline silicon, wherein the gate insulating film is a film formed by laminating a first silicon nitride film having a nitrogen concentration of 6×10²¹ atoms/cc or less and a second silicon nitride film having a nitrogen concentration higher than 6×10²¹ atoms/cc.

A second aspect of the present invention is the first aspect of the present invention, wherein the second silicon nitride film is formed so as to be in contact with the channel layer.

A third aspect of the present invention is the first aspect of the present invention, wherein the nitrogen concentrations in the first and second silicon nitride films are constant in the respective films.

A fourth aspect of the present invention is the first aspect of the present invention, wherein in the second silicon nitride film, the nitrogen concentration in the proximity of an end on a side of the channel layer is higher than the nitrogen concentration in the proximity of an end on a side of the insulating substrate.

A fifth aspect of the present invention is the first aspect of the present invention, wherein the film thickness of the first silicon nitride film is 3/7 to 7/3 times the film thickness of the second silicon nitride film.

A sixth aspect of the present invention is the first aspect of the present invention, wherein an oxygen concentration in an interface between the channel layer and either the first or second silicon nitride film that is in contact with the channel layer is 1×10²¹ atoms/cc or less.

A seventh aspect of the present invention is a method of manufacturing a thin film transistor formed on an insulating substrate, the method including: forming a gate electrode; forming a gate insulating film; and forming a channel layer made of microcrystalline silicon, wherein forming the gate insulating film includes forming a first silicon nitride film having a nitrogen concentration of 6×10²¹ atoms/cc or less by adjusting a flow ratio of a plurality of source gasses and a step of forming a second silicon nitride film having the nitrogen concentration higher than 6×10²¹ atoms/cc by adjusting the flow rate of the plurality of source gasses.

An eighth aspect of the present invention is the seventh aspect of the present invention, wherein the first silicon nitride film, the second silicon nitride film, and the channel layer are formed by a high density plasma CVD method.

A ninth aspect of the present invention is the seventh aspect of the present invention, wherein a step of lowering an oxygen concentration in a surface of either film of the first or second silicon nitride film that forms an interface with the channel layer is included between the step of forming the channel layer and the step of forming either the first or second silicon nitride film that is in contact with the channel layer.

A tenth aspect of the present invention is the ninth aspect of the present invention, wherein the step of lowering the oxygen concentration includes a step of processing a surface of either film of the first or second silicon nitride film that forms an interface with the channel layer using a plasma generated from a hydrogen gas.

An eleventh aspect of the present invention is the ninth aspect of the present invention, wherein the step of lowering the oxygen concentration includes a step of processing a surface of either film of the first or second silicon nitride film that forms an interface with the channel layer using a solution containing hydrofluoric acid.

### Effects of the Invention

According to the first aspect of the present invention, in a thin film transistor having a channel layer that is made of microcrystalline silicon, a gate insulating film is a film formed by laminating a first silicon nitride film having a nitrogen concentration of 6×10²¹ atoms/cc or less and a second silicon nitride film having a nitrogen concentration higher than 6×10²¹ atoms/cc. The second silicon nitride film has a high blocking effect against mobile ions entering from an insulating substrate, making the mobile ions less likely to be stored in an interface with the channel layer. Therefore, even when the thin film transistor is operated under a high temperature environment, an increase in shift amount of the threshold voltage can be suppressed. Furthermore, since the first silicon nitride film is included in the gate insulating film, the gate insulating film has a high dielectric breakdown voltage.

According to the second aspect of the present invention, the second silicon nitride film having a high nitrogen concentration is formed so as to be in contact with the channel layer. Therefore, mobile ions entering from the insulating substrate can be prevented from entering the interface between the channel layer and the gate electrode and from being stored in the interface. As a result, the shift amount of the threshold voltage of the thin film transistor is suppressed.

According to the third aspect of the present invention, the nitrogen concentrations in the first and second silicon nitride films are constant inside the respective films. Therefore, the first and second silicon nitride films can be formed in a simple manner.

According to the fourth aspect of the present invention, in the second silicon nitride film, the nitrogen concentration in an end on a side of the channel layer is higher than the nitrogen concentration on a side of the insulating substrate, thereby making the mobile ions entering from the insulating substrate less likely to be stored in the interface between the channel layer and the gate insulating film. Therefore, the shift amount of the threshold voltage of the thin film transistor can be suppressed. Because the nitrogen concentration inside the second silicon nitride film on a side of the first silicon nitride film is low, the dielectric breakdown voltage becomes high not only in the first silicon nitride film, but also in a portion of the second silicon nitride film. Thus, the dielectric breakdown voltage of the overall gate insulating film becomes higher.

According to the fifth aspect of the present invention, the thickness of the first silicon nitride film is 3/7 to 7/3 times the film thickness of the second silicon nitride film. Therefore, the blocking effect against mobile ions can be improved and the dielectric breakdown voltage can be increased at the same time.

According to the sixth aspect of the present invention, the oxygen concentration in an interface between the channel layer and either the first or second silicon nitride film that is in contact with the channel layer is set at 1×10²¹ atoms/cc or less to decrease the interface state density. This way, the OFF currents of the thin film transistor can be decreased significantly.

According to the seventh aspect of the present invention, the same effects as those of the first aspect can be obtained.

According to the eighth aspect of the present invention, the first silicon nitride film, the second silicon nitride film, and the channel layer can be formed continuously using the same high density plasma CVD device. Therefore, the thin film transistor can be manufactured in a simple manner. Furthermore, these films are formed continuously without being exposed to the atmosphere. Therefore, an impurity and a foreign substance can be prevented from being adhered to a surface of the first silicon nitride film or a surface of the second silicon nitride film.

According to the ninth aspect of the present invention, the same effects as those of the first aspect can be obtained.

According to the tenth aspect of the present invention, a surface of either the first or second silicon nitride film that forms an interface with the channel layer is brought into contact with a hydrogen plasma to securely lower the oxygen concentration on the surface, thereby reducing the OFF currents of the thin film transistor. Furthermore, the adhesion of the channel layer to the first or second silicon nitride film can be improved, and contamination of the interface between them caused by organic substances can be prevented.

According to the eleventh aspect of the present invention, a surface of either the first or second silicon nitride film that forms an interface with the channel layer is brought into contact with a solution containing hydrofluoric acid to lower the oxygen concentration on the surface in a simple manner, thereby reducing the OFF currents of the thin film transistor. Furthermore, the adhesion of the channel layer to either the first or second silicon nitride film can be improved, and contamination of the interface between them caused by organic substances can be prevented.

### BRIEF DESCRIPTION OF THE DRAWINGS

FIG. 1 is a cross-sectional view showing a configuration of a microcrystalline silicon TFT used in a primary study.

FIG. 2 shows a relationship between the nitrogen concentration and the shift amount in the threshold voltage in a silicon nitride film of the microcrystalline silicon TFT shown in FIG. 1.

FIG. 3 shows a relationship between the nitrogen concentration and the dielectric breakdown voltage in a silicon nitride film of the microcrystalline silicon TFT shown in FIG. 1.

FIG. 4 shows a relationship between the gate voltage and the drain current in a microcrystalline silicon TFT that did not undergo a surface treatment of the silicon nitride film.

FIG. 5 shows a relationship between the gate voltage and the drain current in a microcrystalline silicon TFT that has undergone a hydrogen plasma treatment.

FIG. 6 shows a relationship between the gate voltage and the drain current in a microcrystalline silicon TFT that has undergone a hydrofluoric acid treatment.

FIG. 7 is a cross-sectional view showing a cross-sectional configuration of a microcrystalline silicon TFT according to an embodiment of the present invention.

FIG. 8(A) is a drawing showing the nitrogen concentration in the thickness-wise direction of a gate insulating film of the microcrystalline silicon TFT shown in FIG. 7 that is formed by laminating a second silicon nitride film on the upper surface of a first silicon nitride film. FIG. 8(B) is a drawing showing the nitrogen concentration in the thickness-wise direction of a gate insulating film of the microcrystalline silicon TFT shown in FIG. 7 that is formed by laminating the first silicon nitride film on the upper surface of the second silicon nitride film.

FIG. 9 is a cross-sectional view showing the respective process steps of a microcrystalline silicon TFT shown in FIG. 7.

FIG. 10 is a cross-sectional view showing the respective process steps of the microcrystalline silicon TFT shown in FIG. 7.

FIG. 11 is a cross-sectional view showing the respective process steps of the microcrystalline silicon TFT shown in FIG. 7.

FIG. 12 is a chart showing changes in the shift amount of the threshold voltage in an amorphous silicon TFT and a microcrystalline silicon TFT of the present embodiment during a gate bias stress test under a high temperature environment.

FIG. 13(A) is a drawing showing a modification example of changes in the nitrogen concentration when the second silicon nitride film is laminated on the upper surface of the first silicon nitride film. FIG. 13(B) is a drawing showing a modification example of changes in the nitrogen concentration when the first silicon nitride film is laminated on the upper surface of the second silicon nitride film.

FIG. 14(A) is a drawing showing another modification example of changes in the nitrogen concentration when the second silicon nitride film is laminated on the upper surface of the first silicon nitride film. FIG. 14(B) is a drawing showing another modification example of changes in the nitrogen concentration when the first silicon nitride film is laminated on the upper surface of the second silicon nitride film.

### DETAILED DESCRIPTION OF EMBODIMENTS

### 1. Primary Study on Gate Insulating Film

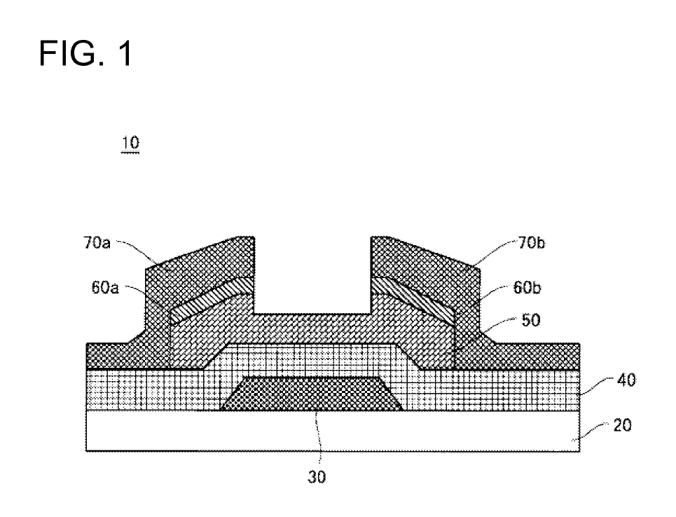

FIG. 1 is a cross-sectional view showing a configuration of a microcrystalline silicon TFT 10 used in a primary study. As shown in FIG. 1, the microcrystalline silicon TFT 10 is a bottom gate type n-channel TFT. A gate electrode 30 made of a metal film is formed on a glass substrate 20, which is an insulating substrate.

A gate insulating film 40 made of a silicon nitride film is formed so as to entirely cover the glass substrate 20 including the gate electrode 30. On the upper surface of the gate insulating film 40, an island-shaped channel layer 50 made of undoped microcrystalline silicon is formed at a location opposite from the gate electrode 30. On the upper surfaces of both edges of the channel layer 50, contact layers 60a and 60b, which are made of silicon doped with a highly concentrated n-type impurity (phosphorus, for example), are arranged respectively. The material for the contact layers 60a and 60b may be either microcrystalline silicon or amorphous silicon.

On the upper surface of the contact layer 60a, a source electrode 70a that is laminated so as to partially overlap the contact layer 60a and that extends to the left side of FIG. 1 is formed. On the upper surface of the contact layer 60b, a drain electrode 70b that is laminated so as to partially overlap the contact layer 60b and that extends to the right side of FIG. 1 is formed. Thus, the source electrode 70a and the drain electrode 70b are ohmically connected to the channel layer 50 through the contact layers 60a and 60b, respectively. In addition, a protective film (not shown in the figure) made of silicon nitride is formed so as to entirely cover the glass substrate 20 including the source electrode 70a and the drain electrode 70b.

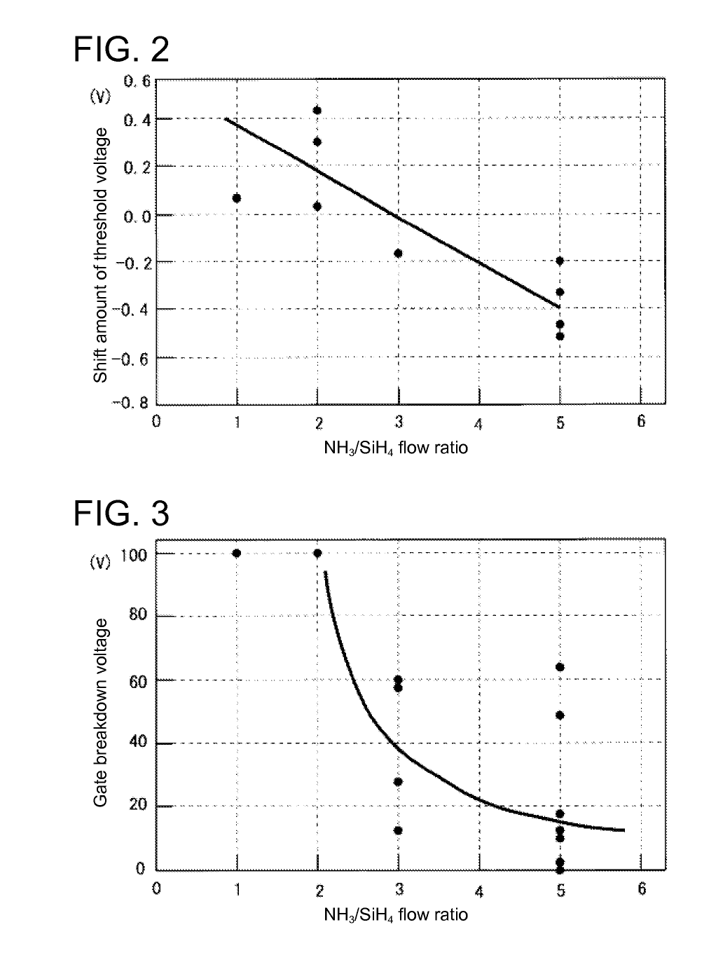

In the microcrystalline silicon TFT 10 shown in FIG. 1, the relationship between the nitrogen concentration in the silicon nitride film, which functions as the gate insulating film 40, and the shift amount of the threshold voltage caused by a gate bias stress test was studied. FIG. 2 is a chart showing the relationship between the nitrogen concentration in the silicon nitride film and the shift amount of the threshold voltage. Here, in FIG. 2, the flow ratio (hereinafter referred to as an “NH₃/SiH₄ flow ratio”) of an ammonia gas (NH₃) to a monosilane gas (SiH₄), which are source gasses of the silicon nitride film, is used instead of the nitrogen concentration. In this case, it means that the higher the NH₃/SiH₄ flow ratio is, the higher the nitrogen concentration inside the silicon nitride film formed is. Here, the shift amount of the threshold voltage means an amount of change showing how much the threshold voltage changed before and after the gate bias stress test. In this gate bias stress test, a voltage of +30V was applied to the gate electrode 30 of the microcrystalline silicon TFT 10 for two hours.

As shown in FIG. 2, the shift amount of the threshold voltage is the largest when the NH₃/SiH₄ flow ratio is 1. As the NH₃/SiH₄ flow ratio increases from 1 to 2, and then from 2 to 3, the shift amount of the threshold voltage becomes smaller. From this, it can be said that, in order to decrease the shift amount of the threshold voltage of the microcrystalline silicon TFT 10 after the gate bias stress test, it is preferable to make the NH₃/SiH₄ flow ratio higher than approximately 2 to increase the nitrogen concentration in the silicon nitride film. Here, when the NH₃/SiH₄ flow ratio is approximately 3 or more, the shift amount of the threshold voltage becomes a negative value. This means that the threshold voltage after the gate bias stress test decreased compared to the threshold voltage before the gate bias stress test. The reason for this decrease in the threshold voltage after the gate bias stress test is unknown.

Next, the relationship between the nitrogen concentration in the silicon nitride film, which functions as the gate insulating film in the microcrystalline silicon TFT 10 shown in FIG. 1, and the gate voltage at the time of a dielectric breakdown in the silicon nitride film (hereinafter referred to as a “dielectric breakdown voltage”) was studied. FIG. 3 is a chart showing the relationship between the nitrogen concentration and the dielectric breakdown voltage in the silicon nitride film. Here, in FIG. 3, the NH₃/SiH₄ flow ratio was used instead of the nitrogen concentration in the same manner as the case of FIG. 2. The film thickness of the silicon nitride film used in this study was 410 nm.

As shown in FIG. 3, when the NH₃/SiH₄ flow ratio is between 1 and 2, the dielectric breakdown voltage is 100V, which is sufficiently high. However, when the NH₃/SiH₄ flow ratio becomes 3 or more, the spread of the dielectric breakdown voltages increases, and the average value of the dielectric breakdown voltage decreases rapidly. For example, when the NH₃/SiH₄ flow ratio is approximately 3, the average value of the dielectric breakdown voltage goes down to approximately 40V. When the NH₃/SiH₄ flow ratio is 5, the average value of the dielectric breakdown voltage goes down to approximately 20V or less. From this, it can be said that, in order to sustain the dielectric breakdown voltage of the silicon nitride film high, it is preferable to make the NH₃/SiH₄ flow ratio approximately 2 or less to lower the nitrogen concentration inside the silicon nitride film.

Although the shift amount of the threshold voltage in the microcrystalline silicon TFT 10 when the gate bias stress test is performed is smaller than the shift amount of the threshold voltage in an amorphous silicon TFT, it still increases under a high temperature environment. Therefore, in order to reduce the shift amount of the threshold voltage as much as possible, it is required to prevent mobile ions from entering from the glass substrate 20 to be stored in the interface with the channel layer 50. Thus, a silicon nitride film having a high blocking effect against mobile ions is used as the gate insulating film 40. In this case, it was found from the above-mentioned study results that a silicon nitride film formed under conditions in which the NH₃/SiH₄ flow ratio was higher than approximately 2 had a high blocking effect against mobile ions. However, it was also found that there was a problem that the dielectric breakdown voltage decreased in a silicon nitride film having a high nitrogen concentration.

As described above, it is difficult to reduce the shift amount of the threshold voltage by controlling the nitrogen concentration in the silicon nitride film and to increase the dielectric breakdown voltage at the same time. From this, it can be said that in order to obtain the gate insulating film 40 that has a low shift amount of the threshold voltage and that has a high dielectric breakdown voltage, two types of silicon nitride films having different nitrogen concentrations need to be laminated.

Here, as described later, the nitrogen concentration in the silicon nitride film is adjusted by adjusting the NH₃/SiH₄ flow ratio of an ammonia gas and a monosilane gas, which are used as source gasses. However, the relationship between the NH₃/SiH₄ flow ratio and the nitrogen concentration varies depending on a plasma CVD device used to form the silicon nitride film. Therefore, the nitrogen concentration in the silicon nitride film that was formed using the plasma CVD device used in the above-mentioned study with the NH₃/SiH₄ flow ratio being adjusted at approximately 2 was measured by a SIMS method (Secondary Ion microprobe Mass Spectrometry). The nitrogen concentration was found to be 6×10²¹ atoms/cc.

When the NH₃/SiH₄ flow ratio obtained in the above-mentioned study is translated into the nitrogen concentration, in a silicon nitride film having the nitrogen concentration of 6×10²¹ atoms/cc or less, the dielectric breakdown voltage is high, but the shift amount of the threshold voltage is large. On the other hand, in a silicon nitride film having the nitrogen concentration higher than 6×10²¹ atoms/cc, it was found that the shift amount of the threshold voltage is low, but the dielectric breakdown voltage is small. From these results, it was found that the gate insulating film 40 that has a small shift amount of the threshold voltage caused by a gate bias stress test and that has a high dielectric breakdown voltage could be obtained by laminating a silicon nitride film having the nitrogen concentration higher than 6×10²¹ atoms/cc and a silicon nitride film having the nitrogen concentration of 6×10²¹ atoms/cc or less. Here, the upper limit of the nitrogen concentration in the silicon nitride films is 1×10²² atoms/cc, which is the atomic density of monocrystalline silicon. The lower limit preferably is as low as possible, and it is currently confirmed down to about 1×10¹⁸ atoms/cc, which is the measuring limit of the SIMS method.

### 2. Primary Study on Interface State Density

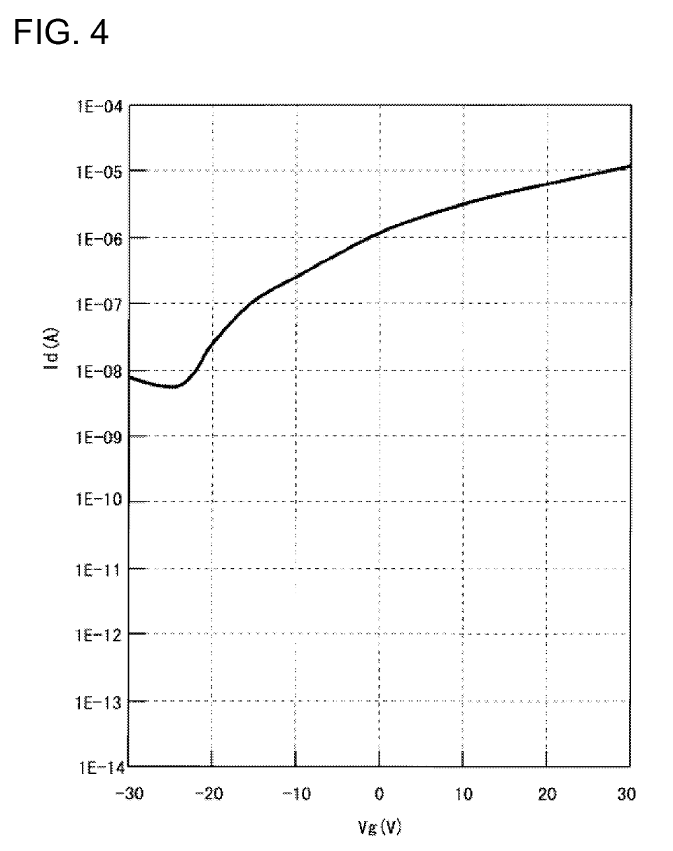

Next, the relationship between the interface state density in the interface between the gate insulating film 40 and the channel layer 50 and drain currents (hereinafter referred to as “OFF currents”), which flow when the microcrystalline silicon TFT 10 is in the OFF state, is studied. FIG. 4 is a chart showing the relationship between the gate voltage and drain currents in the microcrystalline silicon TFT 10 in which, after the silicon nitride film that was to become the gate insulating film 40 was formed, the silicon nitride film did not undergo a surface treatment before a microcrystalline silicon film that was to become the channel layer 50 was formed.

As shown in FIG. 4, OFF currents of approximately 1×10⁻⁸ A are flowing even when a voltage between −20 and −30V is applied to the gate electrode 30 of the microcrystalline silicon TFT 10 and the microcrystalline silicon TFT 10 is in the OFF state. It can be considered that OFF currents are high as described above due to oxygen atoms contained in a natural oxide film formed on a surface of the silicon nitride film or oxygen atoms attached to the surface of the silicon nitride film during the manufacturing process. Specifically, an interface state is formed in the interface between the silicon nitride film and the microcrystalline silicon film due to the oxygen atoms on the surface of the silicon nitride film, and electrons, which are the carriers in the channel layer 50, become trapped in the interface state when the microcrystalline silicon TFT 10 is in the ON state. It is considered that the OFF currents flow when the electrons trapped in the interface state move during the OFF state.

Thus, after the silicon nitride film is formed, if the natural oxide film formed on the surface of the silicon nitride film or the oxygen atoms attached to the surface can be removed before the microcrystalline silicon film is formed, the interface state density is lowered, thereby lowering the OFF currents flowing into the microcrystalline silicon TFT 10. As methods for removing the natural oxide film or oxygen atoms on the surface of the silicon nitride film, there are a method in which a hydrogen plasma treatment is performed on the surface of the silicon nitride film after the silicon nitride film is formed and before the microcrystalline silicon film is formed and a method in which a glass substrate having the silicon nitride film formed thereon is immersed in a hydrofluoric acid solution (hereinafter referred to as a “hydrofluoric acid treatment”). Detailed process conditions for the hydrogen plasma treatment and the hydrofluoric acid treatment are described later.

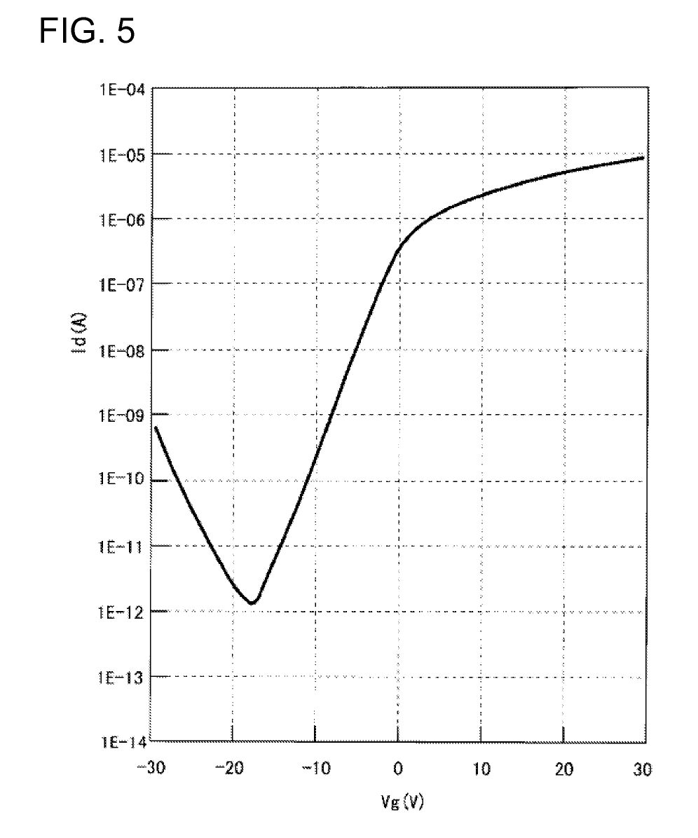

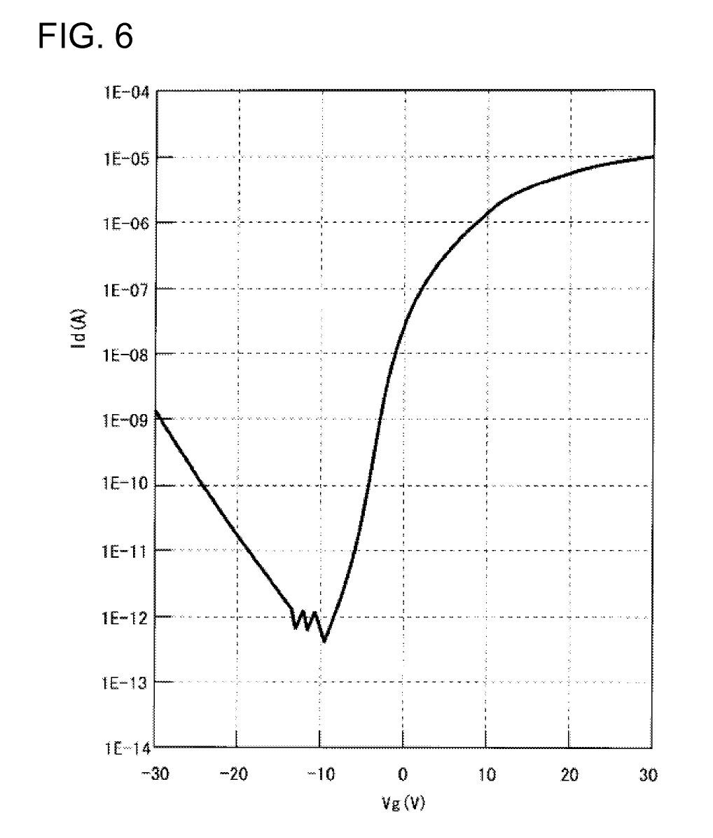

FIG. 5 is a chart showing the relationship between the gate voltage and the drain current in a microcrystalline silicon TFT 10 in which the hydrogen plasma treatment has been performed on the surface of the silicon nitride film. FIG. 6 is a chart showing the relationship between the gate voltage and the drain current in a microcrystalline silicon TFT 10 in which the hydrofluoric acid treatment has been performed on the surface of the silicon nitride film.

As shown in FIG. 5, in the microcrystalline silicon TFT 10 that has undergone the hydrogen plasma treatment, OFF currents become lower than the OFF currents shown in FIG. 4. When the gate voltage is approximately −18V, for example, OFF currents are reduced to approximately 3.0×10⁻¹² A. Thus, it was found that by performing the hydrogen plasma treatment, the OFF currents can be reduced to approximately a several thousand part compared to the microcrystalline silicon TFT 10 that has not undergone the surface treatment of the silicon nitride film shown in FIG. 4.

Furthermore, as shown in FIG. 6, also in the microcrystalline silicon TFT 10 that has undergone the hydrofluoric acid treatment, OFF currents become lower than the OFF currents shown in FIG. 4 during an OFF state. When the gate voltage is approximately −12V, the OFF currents are reduced to approximately 8.0×10⁻¹³ A. Thus, it was found that, by performing the hydrofluoric acid treatment, the OFF currents can be reduced to approximately one-ten-thousandth compared to the microcrystalline silicon TFT 10 that has not undergone the surface treatment of the silicon nitride film shown in FIG. 4.

From these results, it was found that the OFF currents in the microcrystalline silicon TFT 10 can be significantly reduced by performing either the hydrogen plasma treatment or the hydrofluoric acid treatment on the surface of the silicon nitride film, which is to become the gate insulating film 40, before forming the microcrystalline silicon film, which is to become the channel layer 50, to lower the interface state density formed in the interface between the microcrystalline silicon film and the silicon nitride film. Furthermore, by performing either the hydrogen plasma treatment or the hydrofluoric acid treatment on the surface of the silicon nitride film, which is to become the gate insulating film 40, the adhesion of the silicon nitride film to the microcrystalline silicon film, which is to become the channel layer 50, can be improved, and contamination of the interface therebetween by organic substances can be prevented.

On the other hand, as long as the OFF currents in the microcrystalline silicon TFT 10 can be reduced to 1×10⁻¹¹ A or less, a driver circuit that is constituted using such microcrystalline silicon TFTs 10 does not have any problem in terms of operation. Therefore, the oxygen concentration on the surface of the silicon nitride film when the OFF currents were 1×10⁻¹¹ A was measured by the SIMS method, and it was found that the oxygen concentration was 1×10²¹ atoms/cc. From this result, it was found that in order to make the OFF currents of the microcrystalline silicon TFT 10 1×10⁻¹¹ A or less, it is sufficient to make the oxygen concentration on the surface of the silicon nitride film, which is to become the gate insulating film 40, 1×10²¹ atoms/cc or less.

### 3. Configuration of TFT

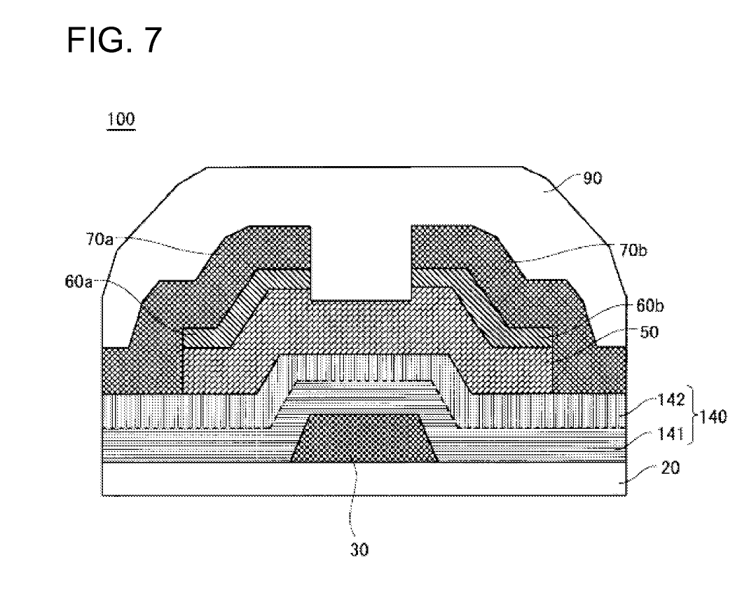

Taking into an account the above-mentioned study results, a configuration of a microcrystalline silicon TFT 100 according to an embodiment of the present invention is described. FIG. 7 is a cross-sectional view showing a cross-sectional configuration of the microcrystalline silicon TFT 100 of an embodiment of the present invention. Unlike the microcrystalline silicon TFT 10 shown in FIG. 1, in the microcrystalline silicon TFT 100 of the present embodiment, a gate insulating film 140 is a film having a configuration in which two layers of silicon nitride films having different levels of nitrogen concentration are laminated. Other components of the microcrystalline silicon TFT 100 are the same as the components of the microcrystalline silicon TFT 10. The same reference characters are given to the same components, and their description is omitted.

The gate oxide film 140 of the microcrystalline silicon TFT 100 is formed of two layers of laminated silicon nitride films. Of the two layers of the silicon nitride films, the film of the lower layer is formed of a silicon nitride film 141 (hereinafter referred to as a “first silicon nitride film 141”) having a nitrogen concentration of 6×10²¹ atoms/cc or less, and its film thickness is 200 nm. The film of the upper layer is formed of a silicon nitride film 142 (hereinafter referred to as a “second silicon nitride film 142”) having a nitrogen concentration higher than 6×10²¹ atoms/cc, and its film thickness is 210 nm. In this case, the second silicon nitride film 142 is a film having a high blocking effect, which prevents mobile ions that enter the gate insulating film 140 mostly from the glass substrate 20 and that move inside the gate insulating film 140 from being stored in the interface with the channel layer 50. Therefore, even when a voltage is applied to the gate electrode 30 for a long time, the mobile ions are less likely to be stored in the interface between the channel layer 50 and the second silicon nitride film because of the blocking effect of the second silicon nitride film 142. Thus, in the microcrystalline silicon TFT 100, the shift amount of the threshold voltage caused by a gate bias stress test becomes smaller.

On the other hand, the dielectric breakdown voltage of the second silicon nitride film 142 is low. As a result, a silicon nitride film having a high dielectric breakdown voltage is needed in order to compensate for the insufficient dielectric breakdown voltage of the second silicon nitride film 142. As such a silicon nitride film having a high dielectric breakdown voltage, the first silicon nitride film 141 is formed. Because the dielectric breakdown voltage of the first silicon nitride film 141 is high, the gate insulating film 140 becomes less likely to have a dielectric breakdown even when a high voltage is applied to the gate electrode 30 of the microcrystalline silicon TFT 100.

Furthermore, because either a hydrogen plasma treatment or a hydrofluoric acid treatment has been performed on the surface of the second silicon nitride film 142, the oxygen concentration on the surface becomes 1×10²¹ atoms/cc or less. The interface state in the interface between the second silicon nitride film 142 and the channel layer 50 is formed by oxygen atoms in the interface. Therefore, the interface state density becomes lower when the oxygen concentration is reduced. Thus, OFF currents of the microcrystalline silicon TFT 100 become significantly reduced.

In the description above, the film thickness ratio between the first silicon nitride film 141 and the second silicon nitride film 142 was set to approximately 1. However, the film thickness ratio does not have to be approximately 1. In order to increase the dielectric breakdown voltage of the gate insulating film 140 particularly for applying a high voltage to the gate electrode 30, for example, the film thickness of the first silicon nitride film 141 can be increased by changing the film thickness ratio of the first silicon nitride film 141 to the second silicon nitride film 142 (hereinafter referred to as a “film thickness ratio”) within the range of 1 to 7/3 without changing the thickness of the entire gate insulating film 140 (in this example, 410 nm). Here, if the film thickness of the first silicon nitride film 141 is made thicker than this film thickness ratio, i.e., if the film thickness ratio becomes higher than 7/3, the film thickness of the second silicon nitride film 142 needs to be decreased by that amount. In that case, the blocking effect of the second silicon nitride film 142 against mobile ions is reduced, and the shift amount of the threshold voltage increases, which is undesirable.

In order to reduce the shift amount of the threshold voltage, the film thickness of the second silicon nitride film 142 can be increased by changing the film thickness ratio within the range of 3/7 to 1. Here, if the thickness of the second silicon nitride film 142 is made thicker than this film thickness ratio, i.e., if the film thickness ratio becomes less than 3/7, the film thickness of the first silicon nitride film 141 needs to be decreased by this amount. In that case, the dielectric breakdown voltage of the first silicon nitride film 141 becomes too low, which is undesirable.

Furthermore, in the description above, of the two layers of laminated silicon nitride films, the film of the lower layer was the first silicon nitride film 141 having a high dielectric breakdown voltage, and the film of the upper layer was the second silicon nitride film 142 having a high blocking effect against mobile ions. However, the gate insulating film 140 may be a film in which the laminating order of the first silicon nitride film 141 and the second silicon nitride film 142 is reversed so that the first silicon nitride film 141 is laminated on the upper surface of the second silicon nitride film 142. However, in this case, either a hydrogen plasma treatment or a hydrofluoric acid treatment needs to be performed on the surface of the first silicon nitride film 141, which is the film of the upper layer.

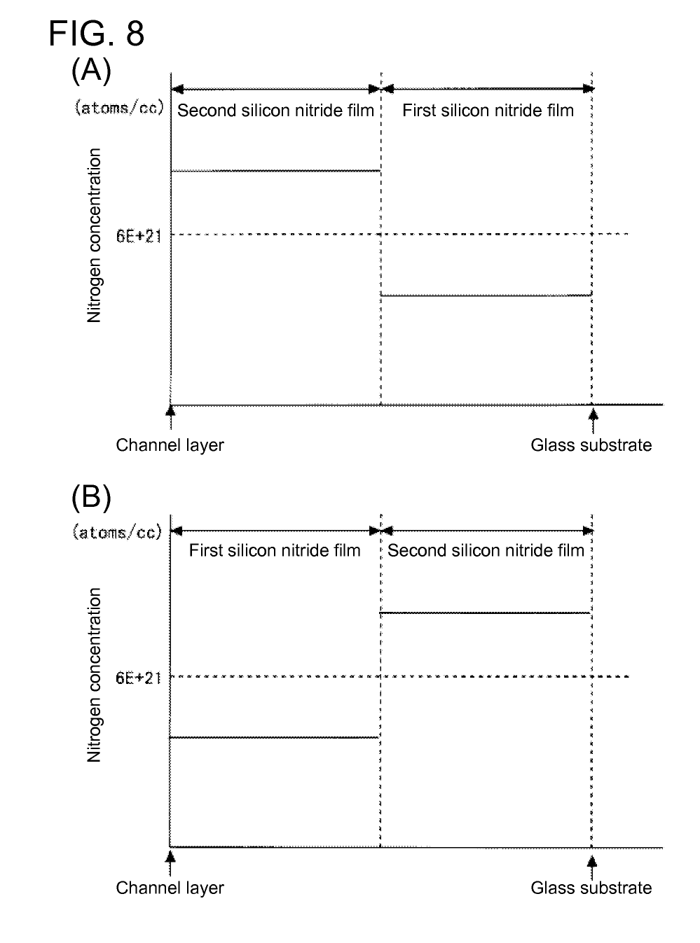

FIG. 8(A) is a drawing showing the nitrogen concentration in the thickness-wise direction of the gate insulating film 140 in which the second silicon nitride film 142 is laminated on the upper surface of the first silicon nitride film 141. FIG. 8(B) is a drawing showing the nitrogen concentration in the thickness-wise direction of the gate insulating film 140 in which the first silicon nitride film 141 is laminated on the upper surface of the second silicon nitride film 142.

As shown in FIG. 8(A), the horizontal axis represents the thickness of the gate insulating film 140. The left end of the horizontal axis represents the interface with the channel layer 50. The right end of the horizontal axis represents the interface with the glass substrate 20. The vertical axis represents the nitrogen concentration inside the gate insulating film 140. FIG. 8(A) shows that the second silicon nitride film 142 having a high nitrogen concentration is laminated on the upper surface of the first silicon nitride film 141 having a low nitrogen concentration. It can be said that the nitrogen concentration is constant in the respective films.

On the other hand, FIG. 8(B) shows that the first silicon nitride film 141 having a low nitrogen concentration is laminated on the upper surface of the second silicon nitride film 142 having a high nitrogen concentration. Like the case of FIG. 8(A), it can be said that the nitrogen concentration is constant in the respective films.

The first and second silicon nitride films 141 and 142, which respectively have a constant nitrogen concentration as described above, can be formed in a simple manner. Furthermore, when the second silicon nitride film 142 is laminated on the upper surface of the first silicon nitride film 141, mobile ions entering from the glass substrate 20 are less likely to be stored in the interface between the channel layer 50 and the gate insulating film 140 compared to when the first silicon nitride film 141 is laminated on the upper surface of the second silicon nitride film 142. Therefore, the shift of the threshold voltage in the microcrystalline silicon TFT 100 caused by a gate bias stress test can be reduced.

### 4. Manufacturing Method of TFT

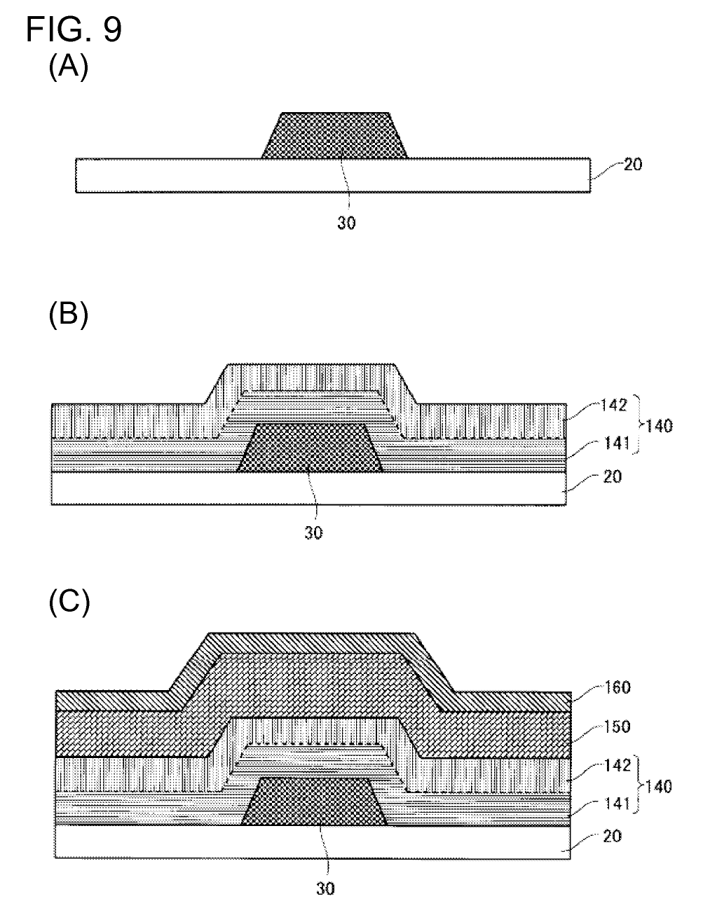

FIGS. 9 to 11 are cross-sectional views showing the respective process steps of the microcrystalline silicon TFT 100 shown in FIG. 7. First, as shown in FIG. 9(A), on the glass substrate 20, which is an insulating substrate, a tantalum nitride (TaN) film of 50 nm in film thickness is formed by a sputtering method, and on the upper surface of the tantalum nitride film, a tungsten film (neither film is shown in the figure) of 200 nm in film thickness is formed continuously. Next, a resist film applied on the upper surface of the tungsten film is patterned using a photolithography technique to form a resist pattern (not shown in the figure) that has a prescribed shape.

Next, using the resist pattern as a mask, the tungsten film and the tantalum nitride film are etched in this order by a dry etching method to form the gate electrode 30, which is formed of a multilayer metal film that includes tantalum nitride and tungsten. The material to form the gate electrode 30 is not particularly limited as long as it is a material that is used for a gate electrode of a conventional TFT, which includes a metal, such as molybdenum, tungsten, tantalum, aluminum, or the like, an alloy of these metals, or the like.

As shown in FIG. 9(B), the resist pattern is removed, and on the glass substrate 20 including the gate electrode 30, the first silicon nitride film 141 is formed by a high density plasma CVD method. The film thickness of the first silicon nitride film 141 is set at 200 nm, for example. As methods for generating a high density plasma, there are various methods, such as an ICP (Inductive Coupled Plasma) method, a surface wave plasma method, an ECR (Electron Cyclotron Resonance Plasma) method, and the like. To form the first silicon nitride film 141, a high density plasma generated by any one of the methods above can be used. For forming the first silicon nitride film 141, a mixed gas containing a monosilane gas and an ammonia gas is used as a source gas. In order to make the nitrogen concentration in the first silicon nitride film 141 to be 6×10²¹ atoms/cc or less, the NH₃/SiH₄ flow ratio of the ammonia gas to the monosilane gas supplied in a chamber of a high density plasma CVD device is adjusted. The relationship between the NH₃/SiH₄ flow ratio and the nitrogen concentration in the silicon nitride film varies depending on a high density plasma CVD device used. In the present embodiment, the high density plasma CVD device that was used in the study shown in FIGS. 2 and 3 was used, and the NH₃/SiH₄ flow ratio was set to 1. The pressure inside the chamber of the high density plasma CVD device was set to between 133 and 1330 Pa, and the RF power was set to between 500 and 1000 W. The substrate temperature was set to between 300 and 500° C.

Then, on the upper surface of the first silicon nitride film 141, the second silicon nitride film 142 of 210 nm in film thickness, for example, is formed by a high density plasma CVD method. In this case, the NH₃/SiH₄ flow ratio is adjusted so as to make the nitrogen concentration in the second silicon nitride film 142 higher than 6×10²¹ atoms/cc using the high density plasma CVD device that formed the first silicon nitride film 141 without changing the pressure inside the chamber, the RF power, and the substrate temperature. The relationship between the NH₃/SiH₄ flow ratio and the nitrogen concentration inside the film varies depending on a high density plasma CVD device used. In the present embodiment, the NH₃/SiH₄ flow ratio was set to 3. By forming the first and second silicon nitride films 141 and 142 by the high density plasma CVD method as described above, the hydrogen plasma treatment and formation of a microcrystalline silicon film, which are described later, can be performed using the same high density plasma CVD device by simply changing the process conditions to continuously form the films and perform the treatments. This way, the microcrystalline silicon TFT 100 can be manufactured in a simple manner. Furthermore, after the first silicon nitride film 141 is formed, the second silicon nitride film 142 is formed continuously without exposing the surface of the first silicon nitride film 141 to the atmosphere. This way, an impurity or a foreign substance can be prevented from being attached to the interface between the first silicon nitride film 141 and the second silicon nitride film 142. These effects also apply to cases described later in which the same device is used to continuously form films and perform treatments.

Here, the first silicon nitride film 141 and the second silicon nitride film 142 may be formed by a plasma CVD (Plasma Enhanced Chemical Vapor Deposition) method using a parallel plate type plasma CVD device.

Next, a hydrogen plasma treatment is performed on the surface of the second silicon nitride film 142. In the high density plasma CVD device that formed the first and second silicon nitride films 141 and 142, the hydrogen plasma treatment can be continuously performed after the first and second silicon nitride films 141 and 142 have been formed by newly setting the gas kinds, the pressure in the chamber, the RF power, and the treatment time. The hydrogen plasma treatment is performed under the following conditions, for example. The flow rate of hydrogen gas (H₂) is set at 1 slm; the RF power is set at 0.1 kW; the pressure inside the chamber is set at 100 Pa; and the treatment time is set at 10 seconds. If the first and second silicon nitride films 141 and 142 are formed using a parallel plate type plasma CVD device, the hydrogen plasma treatment may also be performed using the parallel plate type plasma CVD device.

Alternatively, a hydrofluoric acid treatment may be performed on the surface of the second silicon nitride film 142 instead of the hydrogen plasma treatment. The temperature of the solution used for the hydrofluoric acid treatment is room temperature (20±15° C.), and the concentration of hydrogen fluoride (HF) is 2%. The hydrofluoric acid treatment is performed by immersing the glass substrate 20 in such a solution for 20 seconds.

As shown in FIG. 9(C), on the surface of the second silicon nitride film 142 on which the hydrogen plasma treatment has been performed, a microcrystalline silicon film 150 of 50 nm in film thickness is formed. The microcrystalline silicon film 150, which is to become the channel layer 50, is formed by the high density plasma CVD method. Like the first and second silicon nitride films 141 and 142, the microcrystalline silicon film 150 may be formed by any one of the ICP method, the surface wave plasma method, the ECR method, or the like. However, if it is formed by the same method as that of the first and second silicon nitride films 141 and 142, the films can be continuously formed or treated using the same high density plasma CVD device from the formation of the first silicon nitride film 141 to the formation of the microcrystalline silicon film 150. Furthermore, if the microcrystalline silicon film 150 is formed using the high density plasma CVD device that performed the hydrogen plasma treatment, the surface of the second silicon nitride film 142 is not exposed to the atmosphere after the hydrogen plasma treatment. Therefore, a natural oxide film can be prevented from forming again on the surface of the second silicon nitride film 142.

The source gas used to form the microcrystalline silicon film 150 is a mixed gas of a monosilane gas and a hydrogen gas. The flow ratio (SiH₄/H₂ flow ratio) of the monosilane gas and the hydrogen gas was set to 1/20. The pressure inside the chamber was set to 1.33 Pa, and the substrate temperature was set to 300° C. However, they can be appropriately modified within the following ranges: 1/50 to 1/1 for the SiH₄/H₂ flow ratio; 1.33×10⁻¹ to 4.00×10 Pa for the pressure; and 300 to 400° C. for the substrate temperature. The grain size of the microcrystalline silicon film 150 formed this way is approximately several nm. Here, whether or not the silicon formed is microcrystalline silicon is determined by a Raman spectroscopy analysis method. Specifically, in silicon of 50 nm in film thickness, if a peak intensity Ic that satisfies the relationship of the following formula (I) with respect to a peak intensity Ia of amorphous silicon is observed in the Raman shift region between 380 cm⁻¹ and 580 cm⁻¹, the silicon formed is determined to be microcrystalline silicon.

Ic/Ia=9.0 (1)

Here, instead of the microcrystalline silicon film 150 formed by the high density plasma CVD device, a microcrystalline silicon film obtained by annealing an amorphous silicon layer formed by a plasma CVD method using a laser may be used.

Next, on the upper surface of the microcrystalline silicon film 150, an n⁺ silicon film 160 containing a highly concentrated n-type impurity is formed so as to be ohmically connected to a source electrode 70a and a drain electrode 70b, which are described later. The source gas for forming the n⁺ silicon film 160 is a mixed gas containing a monosilane gas, a hydrogen gas, and a phosphine gas (PH₃). The film thickness of the n⁺ silicon film 160 is 20 nm, for example. The n⁺ silicon film 160 may be either a microcrystalline silicon film formed by a high density plasma CVD device or an amorphous silicon film formed by a parallel plate type plasma device.

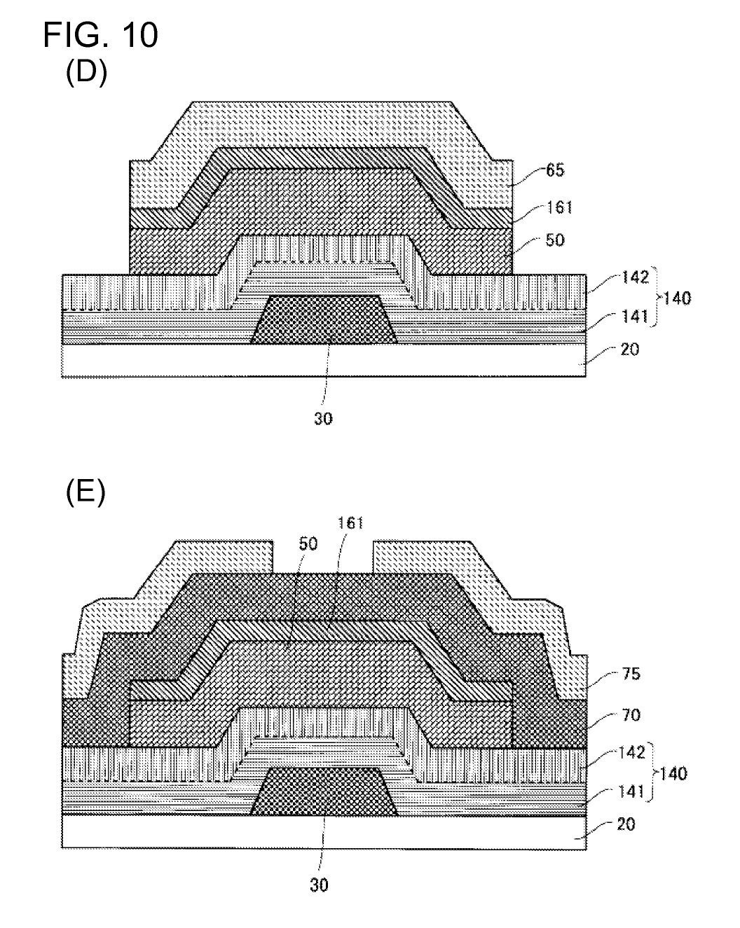

As shown in FIG. 10(D), a resist film applied on the upper surface of the n⁺ silicon film 160 is patterned by a photolithography method to form a resist pattern 65 having a prescribed shape. Then, using the resist pattern 65 as a mask, the n⁺ silicon film 160 and the microcrystalline silicon film 150 are etched in this order by a dry etching method to form an island-shaped n⁺ silicon layer 161 and the channel layer 50.

As shown in FIG. 10(E), after the resist pattern 65 is removed, a metal film 70 film made of molybdenum of 200 nm in film thickness, for example, is formed by a sputtering method over the glass substrate 20. Next, a resist film applied on the metal film 70 is patterned by a photolithography method to form a resist pattern 75 having an opening above the center of the channel layer 50.

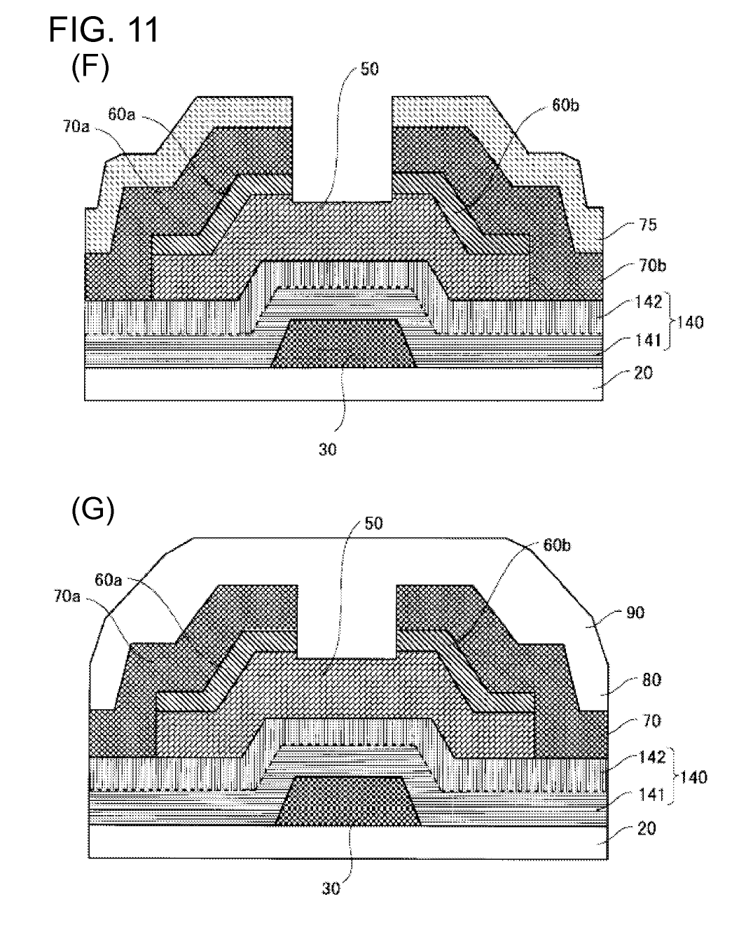

As shown in FIG. 11(F), using the resist pattern 75 as a mask, the metal film 70 and the n⁺ silicon layer 161 are etched in this order by a dry etching method. As a result, the n⁺ silicon layer 161 is separated into a portion on the left and a portion on the right, which form contact layers 60a and 60b, respectively. The metal film 70 is etched to form a source electrode 70a that partially overlaps the upper surface of the contact layer 60a and that extends to the left side of FIG. 11(F) and a drain electrode 70b that partially overlaps the upper surface of the contact layer 60b and that extends to the right side of FIG. 11(F). As a result, the source electrode 70a is ohmically connected to the channel layer 50 through the contact layer 60a, and the drain electrode 70b is ohmically connected to the channel layer 50 through the contact layer 60b. Here, the metal film that becomes the source electrode 70a and the drain electrode 70b is not particularly limited to molybdenum as long as it is a metal film used for a gate electrode of a conventional TFT, such as a metal film obtained by laminating a molybdenum film on the upper surface of an aluminum film, a metal film obtained by laminating a titanium film on the upper surface of an aluminum film, or the like.

As shown in FIG. 11(G), after the resist pattern 75 is removed, a passivation film 90 made of silicon nitride is formed by a plasma CVD method so as to entirely cover the glass substrate 20 to protect the microcrystalline silicon TFT 100.

### 5. Effects

According to the microcrystalline silicon TFT 100 of the above-mentioned embodiments, the gate insulating film 140 is formed of a film obtained by laminating the first silicon nitride film 141 having the nitrogen concentration of 6×10²¹ atoms/cc or less and the second silicon nitride film 142 having the nitrogen concentration higher than 6×10²¹ atoms/cc. In this case, the second silicon nitride film 142 has a high blocking effect against mobile ions entering from the glass substrate 20, thereby making the mobile ions less likely to be stored in the interface between the gate insulating film 140 and the channel layer 50. Furthermore, the first silicon nitride film 141 increases the dielectric breakdown voltage of the gate insulating film 140. This way, an increase in the shift amount of the threshold voltage can be suppressed while sustaining the dielectric breakdown voltage of the gate insulating film 140 high even when the microcrystalline silicon TFT 100 is operated under a high temperature environment.

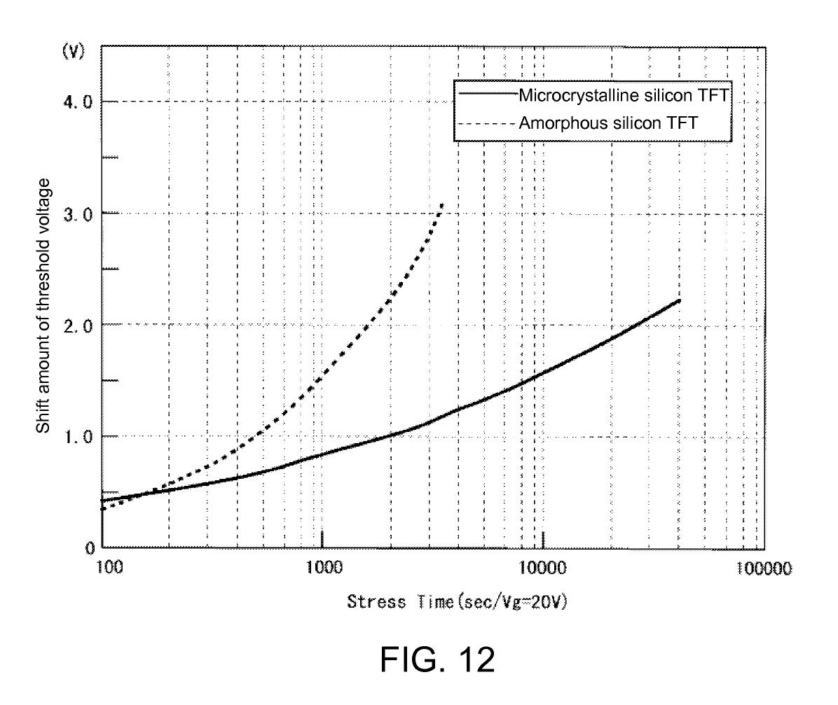

FIG. 12 is a chart showing changes in the shift amount of the threshold voltage in an amorphous silicon TFT and the microcrystalline silicon TFT 100 of the present embodiment during a gate bias stress test under a high temperature environment. In the gate bias stress test of FIG. 12, a voltage of +20V was applied to the gate electrode 30 in an environment in which the temperature was set to 85° C. In the microcrystalline silicon TFT 100, the shift amount of the threshold voltage under a high temperature environment can be suppressed by optimizing the nitrogen concentration in the first and second silicon nitride films 141 and 142, which constitute the gate insulating film 140. Specifically, the time needed for the shift amount of the threshold voltage of the microcrystalline silicon TFT 100 under a high temperature environment to reach 5V can be made 1000 times or more compared to that of the amorphous silicon TFT under a high temperature environment. Therefore, a highly reliable monolithic type liquid crystal display device can be manufactured by constituting a driver circuit using the microcrystalline silicon TFT 100 described above.

Furthermore, the concentration of oxygen attached to the surface of the second silicon nitride film 142 can be lowered by performing either the hydrogen plasma treatment or the hydrofluoric acid treatment on the surface of the second silicon nitride film 142, which is in contact with the channel layer 50. If the oxygen concentration can be lowered to 1×10²¹ or less, OFF currents of the microcrystalline silicon TFT 100 can be reduced to the level that does not cause any problem. Thus, in the microcrystalline silicon TFT 100, OFF currents and the shift amount of the threshold voltage under a high temperature environment can be reduced at the same time.

### 6. Modification Examples

### 6.1 First Modification Examples

In the microcrystalline silicon TFT 100 of the above-mentioned embodiment, the nitrogen concentration was set to be constant inside the first and second silicon nitride films 141 and 142, respectively. However, as described above, it is sufficient if the nitrogen concentration inside the first silicon nitride film 141 is 6×10²¹ atoms/cc or less and the nitrogen concentration inside the second silicon nitride film 142 is higher than 6×10²¹ atoms/cc. As long as these conditions are met, the nitrogen concentration may not be constant inside the first and second silicon nitride films 141 and 142, respectively. Thus, cases in which the nitrogen concentration varies inside the first and second silicon nitride films 141 and 142, respectively, are described below.

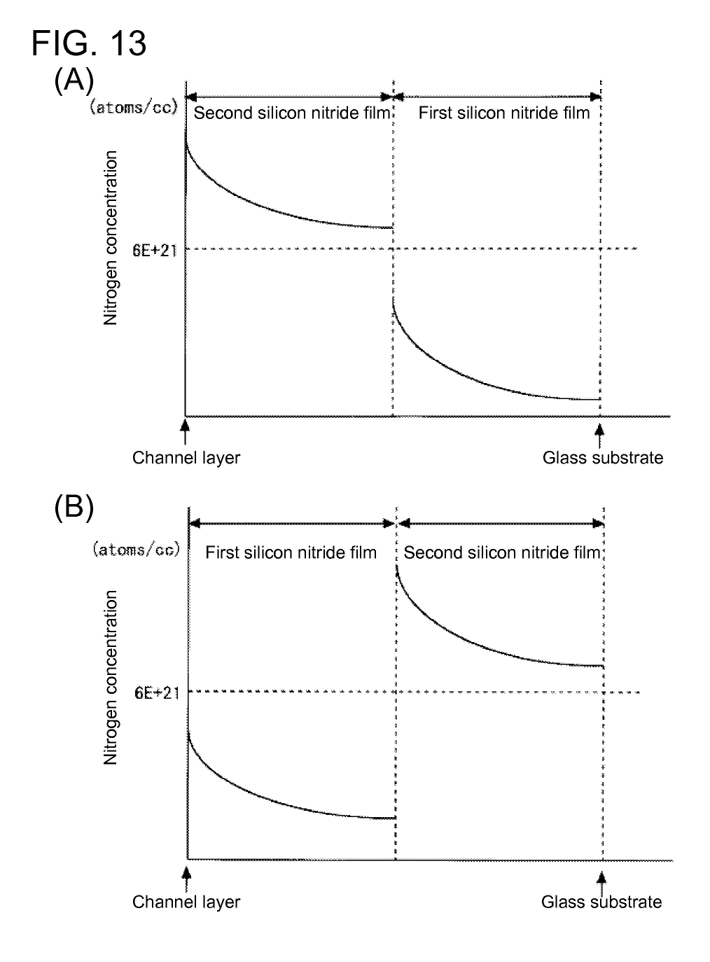

FIG. 13(A) is a drawing showing a modification example of changes in the nitrogen concentration when the second silicon nitride film 142 is laminated on the upper surface of the first silicon nitride film 141. FIG. 13(B) is a drawing showing a modification example of changes in the nitrogen concentration when the first silicon nitride film 141 is laminated on the upper surface of the second silicon nitride film 142. FIG. 13(A) and FIG. 13(B) can be read in the same manner as FIG. 8(A) and FIG. 8(B). Therefore, their description is omitted.

In the case shown in FIG. 13(A), unlike the case shown in FIG. 8(A), the nitrogen concentration inside the second silicon nitride film 142 is the highest at the interface with the channel layer 50, and it decreases monotonically towards the side of the glass substrate 20, reaching the lowest level at the interface with the first silicon nitride film 141. In this case, even at the interface with the first silicon nitride film 141 where the nitrogen concentration becomes the lowest, the nitrogen concentration is higher than 6×10²¹ atoms/cc. Similarly, the nitrogen concentration inside the first silicon nitride film 141 is the highest at the interface with the second silicon nitride film 142, and it decreases monotonically towards the side of the glass substrate 20, reaching the lowest level at the interface with the glass substrate 20. In this case, even at the interface with the second silicon nitride film 142 where the nitrogen concentration is the highest, the nitrogen concentration is 6×10²¹ atoms/cc or less.

In the case shown in FIG. 13(B), the nitrogen concentration inside the second silicon nitride film 142 is the highest at the interface with the first silicon nitride film 141, and it decreases monotonically towards the side of the glass substrate 20, reaching the lowest level at the interface with the glass substrate 20. In this case, even at the interface with the glass substrate 20 where the nitrogen concentration is the lowest, the nitrogen concentration is higher than 6×10²¹ atoms/cc. Similarly, the nitrogen concentration inside the first silicon nitride film 141 is the highest at the interface with the channel layer 50, and it decreases monotonically towards the side of the glass substrate 20, reaching the lowest level at the interface with the second silicon nitride film 142. In this case, even at the interface with the channel layer 50 where the nitrogen concentration is the highest, the nitrogen concentration is 6×10²¹ atoms/cc or less.

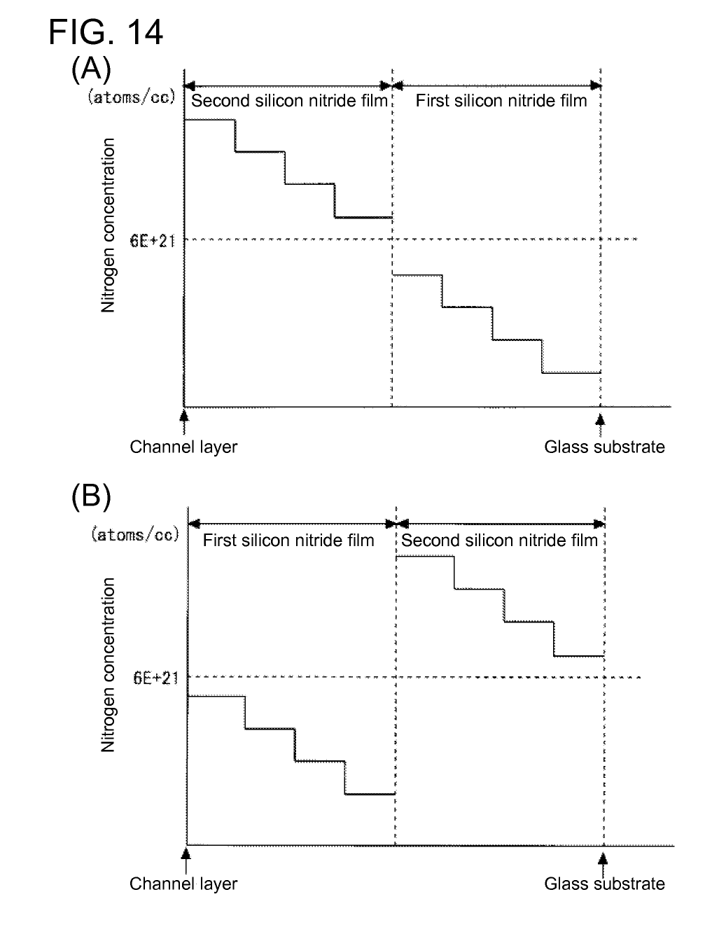

FIG. 14(A) is a drawing showing another modification example of changes in the nitrogen concentration when the second silicon nitride film 142 is laminated on the upper surface of the first silicon nitride film 141. FIG. 14(B) is a drawing showing another modification example of changes in the nitrogen concentration when the first silicon nitride film 141 is laminated on the upper surface of the second silicon nitride film 142. FIG. 14(A) and FIG. 14(B) can be read in the same manner as FIG. 8(A) and FIG. 8(B). Therefore, their description is omitted.

In the case shown in FIG. 14(A), in a manner similar to the case shown in FIG. 13(A), the nitrogen concentration inside the second silicon nitride film 142 is the highest at the interface with the channel layer 50, and it decreases stepwisely towards the side of the glass substrate 20, reaching the lowest level at the interface with the first silicon nitride film 141. In this case, even at the interface with the first silicon nitride film 141 where the nitrogen concentration is the lowest, the nitrogen concentration is higher than 6×10²¹ atoms/cc. Similarly, the nitrogen concentration inside the first silicon nitride film 141 is the highest at the interface with the channel layer 50, and it decreases stepwisely towards the side of the glass substrate 20, reaching the lowest level at the interface with the second silicon nitride film 142. In this case, even at the interface with the second silicon nitride film 142 where the nitrogen concentration is the highest, the nitrogen concentration is 6×10²¹ atoms/cc or less.

In the case shown in FIG. 14(B), the nitrogen concentration inside the second silicon nitride film 142 is the highest at the interface with the first silicon nitride film 141, and it decreases stepwisely towards the side of the glass substrate 20, reaching the lowest level at the interface with the glass substrate 20. In this case, even at the interface with the glass substrate 20 where the nitrogen concentration is the lowest, the nitrogen concentration is higher than 6×10²¹ atoms/cc. Similarly, the nitrogen concentration inside the first silicon nitride film 141 is the highest at the interface with the channel layer 50, and it decreases stepwisely towards the side of the glass substrate 20, reaching the lowest level at the interface with the second silicon nitride film 142. In this case, even at the interface with the channel layer 50 where the nitrogen concentration is the highest, the nitrogen concentration is 6×10²¹ atoms/cc or less.

As shown in FIG. 13(A) and FIG. 14(A), when the nitrogen concentration in the second silicon nitride film 142 is the highest at the interface with the channel layer 50, mobile ions entering from the glass substrate 20 are less likely to be stored in the interface between the channel layer 50 and the gate insulating film 140. Therefore, an increase in the shift amount of the threshold voltage can be suppressed while sustaining the dielectric breakdown voltage of the gate insulating film 140 high even when the microcrystalline silicon TFT 100 is operated under a high temperature environment. Furthermore, in this case, the nitrogen concentration in the second silicon nitride film 142 on the side of the first silicon nitride film 141 becomes low. As a result, the dielectric breakdown voltage becomes high not only in the first silicon nitride film 141, but also in a portion of the second silicon nitride film 142, thereby increasing the dielectric breakdown voltage of the overall gate insulating film 140.

In FIG. 13(A), FIG. 13(B), FIG. 14(A), and FIG. 14(B), the nitrogen concentration inside the first silicon nitride film 141 was set to be high on the side of the channel layer 50 and low on the side of the glass substrate 20. However, it may be reversed such that it is low on the side of the channel layer 50 and high on the side of the glass substrate 20. Alternatively, the nitrogen concentration inside the first silicon nitride film 141 may be constant.

As shown in FIG. 13(A), FIG. 13(B), FIG. 14(A), and FIG. 14(B), in order to change the nitrogen concentration in the respective films of the first and second silicon nitride films 141 and 142 continuously or stepwisely, the NH₃/SiH₄ flow ratio of ammonia gas and monosilane gas, which are the source gasses, needs to be changed continuously or stepwisely in the respective film formation steps.

### 6.2 Second Modification Examples

In the above-mentioned embodiment, the bottom gate type microcrystalline silicon TFTs 100 were described. However, even in a top gate type microcrystalline silicon TFT, effects similar to those of the bottom gate type microcrystalline silicon TFT 100 can be obtained by using a film formed by laminating the above-mentioned first and second silicon nitride films 141 and 142 as a gate insulating film. Furthermore, by performing either a hydrogen plasma treatment or a hydrofluoric acid treatment on a surface of either the first or second silicon nitride film that forms an interface with a channel layer, OFF currents can be reduced in a manner similar to the bottom gate type microcrystalline silicon TFT 100.

The bottom gate type microcrystalline silicon TFT and the top gate type microcrystalline silicon TFT are not limited to an n-channel type, and may be a p-channel type TFT.

### INDUSTRIAL APPLICABILITY

The present invention is applied to a TFT included in a matrix type display device such as an active matrix type liquid crystal display device and the like, and is particularly suitable for TFTs that constitute a driver circuit of a matrix type display device.

### DESCRIPTION OF REFERENCE CHARACTERS

20 glass substrate
30 gate electrode
50 channel layer
100 microcrystalline silicon TFT
140 gate insulating film
141 first silicon nitride film
142 second silicon nitride film

1. A thin film transistor formed on an insulating substrate, comprising:
a gate electrode;
a gate insulating film; and
a channel layer made of microcrystalline silicon,
wherein said gate insulating film is a film formed by laminating a first silicon nitride film having a nitrogen concentration of 6×10²¹ atoms/cc or less and a second silicon nitride film having a nitrogen concentration higher than 6×10²¹ atoms/cc.

2. The thin film transistor according to claim 1, wherein said second silicon nitride film is formed so as to be in contact with said channel layer.

3. The thin film transistor according to claim 1, wherein the nitrogen concentrations in said first and said second silicon nitride films are constant inside the respective films.

4. The thin film transistor according to claim 1, wherein in said second silicon nitride film, the nitrogen concentration in the proximity of an end on a side of said channel layer is higher than the nitrogen concentration in the proximity of an end on a side of said insulating substrate.

5. The thin film transistor according to claim 1, wherein a film thickness of said first silicon nitride film is 3/7 to 7/3 times a film thickness of said second silicon nitride film.

6. The thin film transistor according to claim 1, wherein an oxygen concentration in an interface between said channel layer and either said first or said second silicon nitride film that is in contact with said channel layer is 1×10²¹ atoms/cc or less.

7. A method of manufacturing a thin film transistor formed on an insulating substrate, the method comprising:
forming a gate electrode;
forming a gate insulating film; and
forming a channel layer made of microcrystalline silicon,
wherein forming said gate insulating film includes forming a first silicon nitride film having a nitrogen concentration of 6×10²¹ atoms/cc or less by adjusting a flow ratio of a plurality of source gasses and forming a second silicon nitride film having a nitrogen concentration higher than 6×10²¹ atoms/cc by adjusting the flow rate of said plurality of source gasses.

8. The method of manufacturing a thin film transistor according to claim 7, wherein said first silicon nitride film, said second silicon nitride film, and said channel layer are formed by a high density plasma CVD method.

9. The method of manufacturing a thin film transistor according to claim 7, further comprising a step of lowering an oxygen concentration on a surface of either said first or said second silicon nitride film that forms an interface with said channel layer between the step of forming said channel layer and the step of forming either said first or said second silicon nitride film that is in contact with said channel layer.

10. The method of manufacturing a thin film transistor according to claim 9, wherein said step of lowering the oxygen concentration includes processing a surface of either said first or said second silicon nitride film that forms the interface with said channel layer using a plasma generated from a hydrogen gas.

11. The method of manufacturing a thin film transistor according to claim 9, wherein said step of lowering the oxygen concentration includes a step of processing a surface of either said first or said second silicon nitride film that forms the interface with said channel layer using a solution containing hydrofluoric acid.
